(19) United States
(12) Patent Application Publication
(10) Pub. No.: US 2017/0175250 A1
(43) Pub. Date: Jun. 22, 2017

(54) EVAPORATION SOURCE, EVAPORATION-DEPOSITION DEVICE AND EVAPORATION-DEPOSITION METHOD

(71) Applicants: BOE TECHNOLOGY GROUP CO., LTD., Beijing (CN); Ordos Yuansheng Optoelectronics Co., Ltd., Ordos, Inner Mongolia (CN)

(72) Inventor: Haibing HU, Beijing (CN)

(73) Assignees: BOE TECHNOLOGY GROUP CO. LTD., Beijing (CN); Ordos Yuansheng Optoelecronics Co., Ltd., Ordos, Inner Mongolia (CN)

(21) Appl. No.: 15/129,284

(22) PCT Filed: Mar. 28, 2016
(86) PCT No.: PCT/CN2016/077509

§ 371 Date: Sep. 26, 2016

(30) Foreign Application Priority Data
Apr. 30, 2015 (CN) 201510217702.X

(51) Int. Cl. C23C 14/24; C23C 14/12

(52) U.S. Cl. CPC C23C 14/243; C23C 14/12

(57) ABSTRACT

Disclosed are an evaporation source, an evaporation-deposition device and an evaporation-deposition method. The evaporation source comprises: a crucible configured to generate an evaporation-deposition gas; a crucible top cover arranged on the crucible to seal the crucible; and a plurality of crucible nozzles arranged on the crucible top cover and configured to spray the evaporation-deposition gas from the crucible. The evaporation source further comprises a clogging heater configured to heat the crucible nozzles. The clogging heater may directly heat the crucible nozzle, so as to evaporate the coagulated organic evaporation-deposition material. According to the disclosure, a pressure inside the crucible can be kept constant, ensuring that an article can have an organic evaporation-deposition material layer with uniform thickness.

### FIELD OF THE INVENTION

The disclosure relates to the technical field of evaporation-deposition apparatus, and in particular to an evaporation source, an evaporation-deposition device and an evaporation-deposition method.

### BACKGROUND OF THE INVENTION

OLEDs (Organic Light-Emitting Diode, OLED) have excellent characteristics of, for example, self-illumination, no backlight, high contrast ratio, thinness, wide angle of view, rapid reaction speed, usability of flexible panel, widely applicable temperature range, simple construction and easy manufacture. Therefore, the OLED is considered to be emerging application technologies of next generation flat-display.

At present, an evaporation-deposition apparatus is mainly used to manufacture the OLEDs. Under normal conditions, the evaporation-deposition apparatus is provided with a plurality of organic evaporation-deposition chambers. An evaporation source is provided in each organic evaporation-deposition chamber. The evaporation source includes a crucible and crucible nozzle(s). An organic evaporation-deposition material may be heated to spray out from the crucible nozzle, so as to perform the evaporation-deposition on a substrate. In particular, in the manufacturing processes of the OLED, the organic evaporation-deposition material can be first heated by the crucible provided in the evaporation source, and then, after molecules of the organic evaporation-deposition material are homogenized by heating, the crucible nozzle in the evaporation source can evaporate and deposit the heated molecules of the organic evaporation-deposition material onto the substrate.

FIG. 1 is a structural diagram schematically illustrating an evaporation source in prior art. The evaporation source 1 includes a crucible 11, a crucible top cover 12 and crucible nozzles 13. The crucible 11 can be used to store and heat organic evaporation-deposition materials. The crucible top cover 12 can be used to seal the crucible 11. The crucible nozzles 13 can be used to spray out evaporation-deposition gas from the crucible 11. In the processes of evaporation-deposition, the organic evaporation-deposition material can be first heated by the crucible 11 provided in the evaporation source 1, and then, after the molecules of the organic evaporation-deposition material are homogenized by heating, the crucible nozzles 13 in the evaporation source 1 can evaporate and deposit the heated molecules of the organic evaporation-deposition material onto the substrate. Since there is a temperature difference formed between the nozzles 13 and the heated organic evaporation-deposition material, or since foreign matters may be attached to an inner wall of the nozzle, the evaporated organic evaporation-deposition material may be coagulated at the crucible nozzles 13, thereby resulting in clogging of the crucible nozzles 13. The clogged nozzles 13 may lead to a variation of pressure inside the crucible 11, so that the thickness homogeneity of the evaporated and deposited organic evaporation-deposition material is deteriorated. The crucible nozzles 13 in the evaporation source 1 in the prior art have a clogging rate of approximately 10%-15%. The evaporation-deposition apparatus in the prior art is a vacuum apparatus which is usually provided with 10 organic evaporation-deposition chambers (including a plurality of evaporation sources). The organic evaporation-deposition chambers need to be simultaneously vacuumized. If a crucible nozzle 13 in one of evaporation sources 1 is clogged, then all the organic evaporation-deposition chambers may be caused to go out of service. It would take an operator a plenty of time to resolve the clogging problem of the crucible nozzle 13. Generally speaking, at least 7 hours would be need to resolve the clogging problem of the crucible nozzle 13 (for example, 2 hours for cooling, 1 hour for relieving vacuum, 1 hour for handling the clogging of the nozzle 13, 1 hour for vacuumizing, and 2 hours for reheating). As a result, the organic evaporation-deposition materials in other organic evaporation-deposition chambers may be heavily wasted, thereby influencing the yield of article and the performance of apparatus.

### SUMMARY OF THE INVENTION

In order to resolve above problems, there is provided an evaporation source which can avoid the clogging of nozzle to improve the yield and the performance of apparatus in the disclosure.

According to the disclosure, the evaporation source comprises: a crucible configured to generate an evaporation-deposition gas; a crucible top cover arranged on the crucible to seal the crucible; and a plurality of crucible nozzles arranged on the crucible top cover and configured to spray the evaporation-deposition gas from the crucible. Further, the evaporation source further comprises a clogging heater configured to heat the crucible nozzles.

Preferably, the clogging heater is arranged on the crucible top cover.

Preferably, the evaporation source includes a plurality of clogging heaters, such that each of crucible nozzles corresponds to a respective clogging heater.

Preferably, the clogging heater encompasses the plurality of crucible nozzles.

Preferably, the evaporation source includes a plurality of clogging heaters which encompass the plurality of crucible nozzles in a stacked manner.

Preferably, the clogging heater includes a heating wire which is wound around the crucible nozzles.

Preferably, the evaporation source further comprises a driver which is provided with a clogging sensor to detect whether the crucible nozzle is clogged and which is able to drive the clogging sensor to move.

Preferably, the evaporation source further comprises a driver to which the clogging heater is arranged and which is able to drive the clogging heater to move.

Preferably, the driver is provided with a clogging sensor to detect whether the crucible nozzle is clogged, and the driver is able to drive the clogging heater to move.

Further preferably, the clogging sensor is configured to detect whether the crucible nozzle is clogged on the basis of a rate or a temperature of gas sprayed from the crucible nozzle.

Preferably, the evaporation source is a linear evaporation source, and the plurality of crucible nozzles are distributed in a longitudinal direction of the crucible of the evaporation source.

In addition, there is provided an evaporation-deposition device including any one of evaporation sources as described above.

In addition, there is provided an evaporation-deposition method including steps of: utilizing the evaporation-deposition device as described above to perform an evaporation-deposition process; and utilizing the clogging heater to heat the clogged crucible nozzle when the crucible nozzle is clogged.

The evaporation source according to the disclosure is provided with the clogging heater. When the clogging status of the crucible nozzle occurs, the clogging heater can heat the clogged crucible nozzle, so as to evaporate the coagulated organic evaporation-deposition material. In such a manner, a pressure inside the crucible can be kept constant, ensuring that an article can have an organic evaporation-deposition material layer with uniform thickness. Also, the evaporation-deposition device according to the disclosure can individually heat the clogged crucible nozzle, such that all the organic evaporation-deposition chambers (including the organic evaporation-deposition chamber in which the clogged crucible nozzle is present) can be kept operable. Therefore, a waste of organic evaporation-deposition material can be avoided. Further, the yield of article and the performance of apparatus would not be influenced.

### BRIEF DESCRIPTION OF THE DRAWINGS

FIG. 1 is a structural diagram schematically illustrating an evaporation source in prior art;

FIG. 2 is a structural diagram schematically illustrating an evaporation source according to a first embodiment of the disclosure;

FIG. 3 is a side view schematically illustrating the evaporation source according to the first embodiment of the disclosure;

FIG. 4 is a top plan view schematically illustrating a clogging heater of an evaporation source according to a second embodiment of the disclosure;

FIG. 5 is a front view schematically illustrating a clogging heater of an evaporation source according to a third embodiment of the disclosure;

FIG. 6 is a top plan view schematically illustrating a clogging heater of an evaporation source according to a fourth embodiment of the disclosure;

FIG. 7 is a structural diagram schematically illustrating an evaporation source according to a fifth embodiment of the disclosure;

FIG. 8 is a structural diagram schematically illustrating an evaporation source according to a sixth embodiment of the disclosure; and

FIG. 9 is a structural diagram schematically illustrating an evaporation source according to a seventh embodiment of the disclosure.

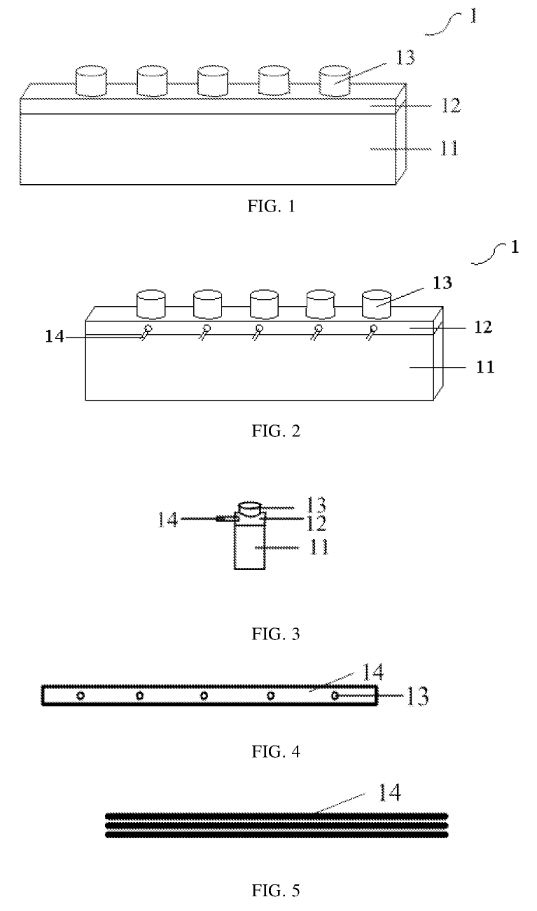

### REFERENCE NUMERAL LIST

1: evaporation source; 11: crucible; 12: crucible top cover; 13: crucible nozzle; 14: clogging heater; 15: clogging sensor; 16: driver

### DETAILED DESCRIPTION OF THE EMBODIMENTS

In order to better understand the technical solutions of the disclosure by those skilled in the art, the disclosure will be further described in detail in conjunction with the accompanying drawings and specific embodiments. In the following description, identical members will be indicated by identical reference numerals.

### First Embodiment

FIG. 2 is a structural diagram schematically illustrating an evaporation source according to a first embodiment of the disclosure. As shown in FIG. 2, there is provided an evaporation source 1 in the first embodiment of the disclosure, including: a crucible 11 configured to generate an evaporation-deposition gas; a crucible top cover 12 arranged on the crucible 11 to seal the crucible 11; and a plurality of crucible nozzles 13 arranged on the crucible top cover 12 and configured to spray the evaporation-deposition gas from the crucible 11. The evaporation source 1 according to the first embodiment of the disclosure further comprises a clogging heater 14 configured to heat the crucible nozzle 13.

Preferably, the clogging heater 14 is arranged in the crucible top cover 12 or on the crucible top cover 12.

In other words, the crucible 11 which loads and heats the organic evaporation-deposition material can be provided with the crucible top cover 12, and the crucible nozzles 13 are arranged on the crucible top cover 12. In this case, the clogging heater 14 can be positioned within the crucible top cover 12 at a position corresponding to the crucible nozzle 13.

In this embodiment, the evaporation source 1 may have a plurality of clogging heaters 14, such that each of crucible nozzles 13 can correspond to a respective clogging heater 14. In such a manner, this can ensure that any one of crucible nozzles 13 can be heated when it is clogged.

As could be seen in FIG. 3, the clogging heaters 14 are arranged in the crucible top cover 12. When the organic evaporation-deposition material to be evaporated is coagulated in a certain crucible nozzle 13, the clogging heater 14 can directly heat the crucible nozzle 13, so as to evaporate the coagulated organic evaporation-deposition material. In such a manner, a pressure inside the crucible 11 can be kept constant, ensuring that an article can have an organic evaporation-deposition material layer with uniform thickness and avoiding a waste of the organic evaporation-deposition material. Further, the yield of article and the performance of apparatus would not be influenced.

In this embodiment, evaporation source 1 is a linear evaporation source, and the plurality of crucible nozzles 13 are distributed in a longitudinal direction of the crucible 11 of the evaporation source 1.

Of course, the evaporation source in this embodiment is not limited to the linear evaporation source. In other embodiments, the plurality of crucible nozzles 13 may also be distributed in other manners, such as an interlacing distribution.

### Second Embodiment

FIG. 4 is a top plan view schematically illustrating a clogging heater of an evaporation source according to a second embodiment of the disclosure. The evaporation source in this embodiment is different from the evaporation source in the first embodiment in that the clogging heater 14 is arranged around the crucible nozzles 13 on the crucible top cover 12. In other words, the clogging heater 14 can encompass the plurality of crucible nozzles 13 located on the crucible top cover 12.

In this embodiment, the clogging heater 14 can encompass all of the crucible nozzles 13 or some of crucible nozzles 13. Therefore, no matter which crucible nozzle 13 is clogged, the clogged crucible nozzle can be heated to evaporate the coagulated organic evaporation-deposition material. In the case that the plurality of crucible nozzles 13 are distributed in the longitudinal direction of the crucible 11 of the evaporation source 1, the clogging heater 14 according to this embodiment can provide a relatively uniform heating with a simple structure.

### Third Embodiment

FIG. 5 is a front view schematically illustrating a clogging heater of an evaporation source according to a third embodiment of the disclosure. The evaporation source in this embodiment is different from the evaporation source in the second embodiment in that the evaporation source 1 has a plurality of clogging heaters 14 which can encompass the plurality of crucible nozzles 13 located on the crucible top cover 12 in a stacked manner.

In this embodiment, the clogging heaters 14 are arranged in a stacked manner, thereby improving the heating effect of the crucible nozzles 13. The number of the clogging heater 14 can be selected on the basis of a height of the crucible nozzle 13 and a specific application.

### Fourth Embodiment

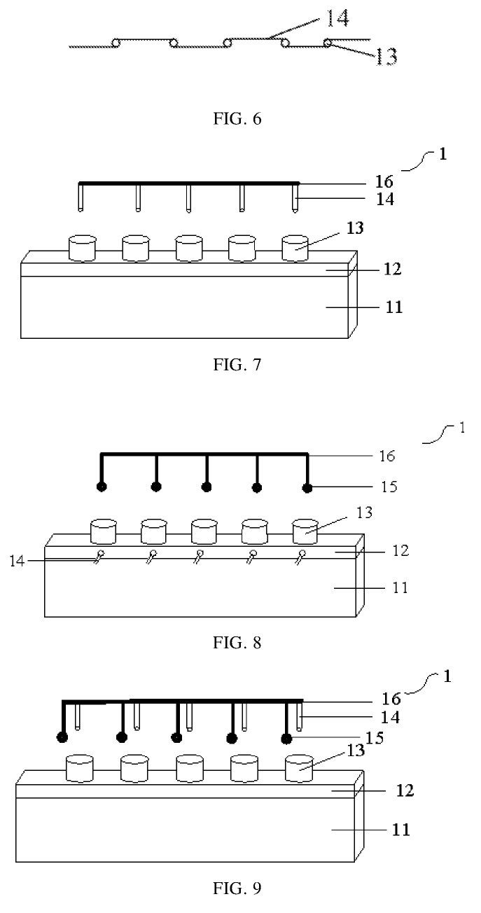

FIG. 6 is a top plan view schematically illustrating a clogging heater of an evaporation source according to a fourth embodiment of the disclosure. The evaporation source in this embodiment is different from the evaporation source in the first embodiment in that the clogging heater 14 includes a heating wire which can be wound around the crucible nozzle 13. In this embodiment, the number of turns of the heating wire wound around the crucible nozzle 13 can be selected on the basis of a height of the crucible nozzle 13 and a specific application. It could be readily understood that, for the plurality of crucible nozzles 13, the number of turns of the heating wire may be different or same. In such a manner, the clogging heater 14 can more efficiently heat the crucible nozzles 13.

### Fifth Embodiment

FIG. 7 is a structural diagram schematically illustrating an evaporation source according to a fifth embodiment of the disclosure. As shown in FIG. 7, the evaporation source in this embodiment is different from the evaporation sources in the first to fourth embodiments in that the evaporation source 1 further includes a driver 16 to which the clogging heater 14 is arranged and which is able to drive the clogging heater 14 to move.

As described above, the driver 16 is arranged above the crucible 11, the clogging heater 14 is arranged to the driver 16, and the driver 16 can drive the clogging heater 14 to move. When the organic evaporation-deposition material to be evaporated is coagulated in the crucible nozzle 13, the driver 16 may drive the clogging heater 14 to move to the clogged crucible nozzle 13. When it is positioned over the clogged crucible nozzle 13, the clogging heater 14 may directly heat the crucible nozzle 13 so as to evaporate the clogged organic evaporation-deposition material. In such a manner, a pressure inside the crucible 11 can be kept constant, ensuring that an article can have an organic evaporation-deposition material layer with uniform thickness and avoiding a waste of the organic evaporation-deposition material. Further, the yield of article and the performance of apparatus would not be influenced.

It would be readily understood that, in this embodiment, a single clogging heater 14 can be used to heat a plurality of crucible nozzles 13.

### Sixth Embodiment

FIG. 8 is a structural diagram schematically illustrating an evaporation source according to a sixth embodiment of the disclosure. The evaporation source in this embodiment is different from the evaporation sources in the first to fourth embodiments in that the evaporation source 1 further comprises a driver 16 on which clogging sensors 15 are provided to detect whether the crucible nozzle 13 is clogged and which is able to drive the clogging sensor 15 to move.

Preferably, the clogging sensor 15 is configured to detect whether the crucible nozzle 13 is clogged on the basis of a rate or a temperature of gas sprayed from the crucible nozzle 13.

Of course, the clogging sensor 15 is not limited by detecting whether the crucible nozzle 13 is clogged on the basis of a rate or a temperature of gas sprayed from the crucible nozzle 13, but can detect the presence of clogging on the basis of other parameters.

In particular, the clogging sensor 15 could be a clogging probe or other types of sensors that can detect the clogging of the crucible nozzle 13.

As described above, the driver 16 is provided with the clogging sensor 15 and can drive the clogging sensor 15 to move. The clogging sensor 15 can detect whether the crucible nozzle 13 is clogged on the basis of a rate or a temperature of gas sprayed from the crucible nozzle 13. When the clogging of the crucible nozzle 13 is detected, a heating process can be performed by a clogging heater 14 corresponding to the clogged crucible nozzle 13.

For example, the clogging sensor 15 may detect the clogging status of the crucible nozzle 13 once every a time interval, so as to find the clogged crucible nozzle 13 in time. Preferably, the clogging sensor 15 arranged on the driver 16 can be moved to a position above the crucible nozzle 13 only when detecting the clogging status of the crucible nozzle 13, but it can be removed in the non-detection time.

The clogging sensor 15 provided in this embodiment can directly determine the clogged crucible nozzle 13. Therefore, the clogging heater 14 can heat the clogged crucible nozzle 13. In such a manner, it is not necessary to heat all of the crucible nozzles 13, but only to heat the clogged crucible nozzle 13. Therefore, normal operations of unclogged crucible nozzles 13 would not be influenced, thereby saving a total amount of heating.

### Seventh Embodiment

FIG. 9 is a structural diagram schematically illustrating an evaporation source according to a seventh embodiment of the disclosure. The evaporation source in this embodiment is different from the evaporation source in the fifth embodiment in that the driver 16 is provided with clogging sensors 15 to detect whether the crucible nozzle 13 is clogged and the driver 16 is able to drive the clogging sensor 15 to move.

In other words, as shown in FIG. 9, the driver 16 is provided with the clogging heater 14 and the clogging sensor 15 to detect whether the crucible nozzle 13 is clogged, and the driver 16 is able to drive the clogging heater 14 and the clogging sensor 15 to move. In this embodiment, the clogging sensor 15 can detect the clogging status; if the clogging of the crucible nozzle 13 is found, then the driver 16 may move a relevant clogging heater 14 to the clogged crucible nozzle 13 to heat it.

In addition, there is provided an evaporation-deposition device in the disclosure, which comprises one of the evaporation sources according to the first to seventh embodiments.

The evaporation-deposition device according to the disclosure is provided with the clogging heater. When the clogging status of the crucible nozzle occurs, the clogging heater can heat the clogged crucible nozzle, so as to evaporate the coagulated organic evaporation-deposition material. In such a manner, a pressure inside the crucible can be kept constant, ensuring that an article can have an organic evaporation-deposition material layer with uniform thickness. Also, the evaporation-deposition device according to the disclosure can individually heat the clogged crucible nozzle, such that all of the organic evaporation-deposition chambers (including the organic evaporation-deposition chamber in which the clogged crucible nozzle is present) can be kept operable. Therefore, a waste of organic evaporation-deposition material can be avoided. Further, the yield of article and the performance of apparatus would not be influenced.

In addition, there is provided an evaporation-deposition method in the disclosure, which comprises steps of: utilizing above evaporation-deposition device to perform an evaporation-deposition process; and utilizing the clogging heater to heat the clogged crucible nozzle when the crucible nozzle is clogged.

In fact, the clogging heater may continuously heat the crucible nozzles. In this case, the clogging of the crucible nozzles can be efficiently avoided.

However, in order to economize, preferably, in the process of the evaporation-deposition, the clogging sensor provided in the evaporation source can be used to detect the clogging status of the crucible nozzles. In particular, the clogging sensor can be moved to a position above the crucible nozzle, and the clogging sensor can detect a temperature of gas sprayed from the crucible nozzle to judge whether the crucible nozzle is clogged and to determine the position of the clogged crucible nozzle.

If the clogging of a crucible nozzle is determined according to the detection result of the clogging sensor, then a clogging heater corresponding to the crucible nozzle may be used to heat the clogged crucible nozzle.

The clogging sensor can be arranged to detect the clogging status of the crucible nozzle once every a time interval, so as to find the clogged crucible nozzle in time. Of course, the clogging sensor is not limited by detecting whether the crucible nozzle is clogged on the basis of a rate or a temperature of gas sprayed from the crucible nozzle, but can detect the presence of clogging on the basis of other parameters.

In this embodiment of the disclosure, the clogged crucible nozzle can be directly determined according to the clogging sensor, so as to heat the clogged crucible nozzle. In such a manner, it is not necessary to heat all of the crucible nozzles, but only to heat the clogged crucible nozzle. Therefore, normal operations of unclogged crucible nozzles 13 would not be influenced, thereby saving a total amount of heating.

It should be understood that the above implementations are merely exemplary embodiments for the purpose of illustrating the principle of the disclosure, and the disclosure is not limited thereto. Various modifications and improvements can be made by a person having ordinary skill in the art without departing from the spirit and essence of the disclosure. Accordingly, all of the modifications and improvements also fall into the protection scope of the disclosure.

1-13. (canceled)

14. An evaporation source comprising:
a crucible configured to generate an evaporation-deposition gas;
a crucible top cover arranged on the crucible to seal the crucible; and
a plurality of crucible nozzles arranged on the crucible top cover and configured to spray the evaporation-deposition gas from the crucible,
wherein the evaporation source further comprises a clogging heater configured to heat the crucible nozzles.

15. The evaporation source according to claim 14, wherein
the clogging heater is arranged on the crucible top cover.

16. The evaporation source according to claim 15, wherein
the evaporation source includes a plurality of clogging heaters, such that each of crucible nozzles corresponds to a respective clogging heater.

17. The evaporation source according to claim 15, wherein
the clogging heater encompasses the plurality of crucible nozzles.

18. The evaporation source according to claim 17, wherein
the evaporation source includes a plurality of clogging heaters which encompass the plurality of crucible nozzles in a stacked manner.

19. The evaporation source according to claim 15, wherein
the clogging heater includes a heating wire which is wound around the crucible nozzles.

20. The evaporation source according to claim 14, wherein
the evaporation source further comprises a driver which is provided with a clogging sensor to detect whether the crucible nozzle is clogged and which is able to drive the clogging sensor to move.

21. The evaporation source according to claim 14, wherein
the evaporation source further comprises a driver to which the clogging heater is arranged and which is able to drive the clogging heater to move.

22. The evaporation source according to claim 21, wherein
the driver is provided with a clogging sensor to detect whether the crucible nozzle is clogged, and
the driver is able to drive the clogging heater to move.

23. The evaporation source according to claim 20, wherein
the clogging sensor is configured to detect whether the crucible nozzle is clogged on the basis of a rate or a temperature of gas sprayed from the crucible nozzle.

24. The evaporation source according to claim 22, wherein
the clogging sensor is configured to detect whether the crucible nozzle is clogged on the basis of a rate or a temperature of gas sprayed from the crucible nozzle.

25. The evaporation source according to claim 14, wherein
the evaporation source is a linear evaporation source, and
the plurality of crucible nozzles are distributed in a longitudinal direction of the crucible of the evaporation source.

26. An evaporation-deposition device including the evaporation source according to claim 14.

27. The evaporation-deposition device according to claim 26, wherein
the evaporation source further comprises a driver which is provided with a clogging sensor to detect whether the crucible nozzle is clogged and which is able to drive the clogging sensor to move.

28. The evaporation-deposition device according to claim 26, wherein the evaporation source further comprises a driver to which the clogging heater is arranged and which is able to drive the clogging heater to move.

29. The evaporation-deposition device according to claim 28, wherein
the driver is provided with a clogging sensor to detect whether the crucible nozzle is clogged, and
the driver is able to drive the clogging heater to move.

30. An evaporation-deposition method, wherein the method includes steps of:
utilizing the evaporation-deposition device according to claim 26 to perform an evaporation-deposition process; and
utilizing the clogging heater to heat the clogged crucible nozzle when the crucible nozzle is clogged.

31. The evaporation-deposition method according to claim 30, wherein
the evaporation source further comprises a driver which is provided with a clogging sensor to detect whether the crucible nozzle is clogged and which is able to drive the clogging sensor to move.

32. The evaporation-deposition method according to claim 30, wherein
the evaporation source further comprises a driver to which the clogging heater is arranged and which is able to drive the clogging heater to move.

33. The evaporation-deposition method according to claim 32, wherein
the driver is provided with a clogging sensor to detect whether the crucible nozzle is clogged, and
the driver is able to drive the clogging heater to move.
